(19) United States
(12) Patent Application Publication
(10) Pub. No.: US 2007/0233915 A1
(43) Pub. Date: Oct. 4, 2007

(54) PCMICA CARD

(75) Inventor: SZU-WEI KUO, Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/555,241

(22) Filed: Oct. 31, 2006

(30) Foreign Application Priority Data
Mar. 2, 2006 (CN) 200620055849.X

(51) Int. Cl. G06F 13/12; H05K 7/10

(52) U.S. Cl. 710/74; 710/301

(57) ABSTRACT

An exemplary PCMCIA card includes a USB interface, a PCMCIA interface, an interface switch, a first control circuit, a second control circuit, and a memory module. The first control circuit is connected between the PCMCIA interface and the memory module. The second control circuit is connected between the USB interface and the memory module. The interface switch is connected between the first control circuit and the second control circuit. The interface switch is changed between a first state, and a second state. When the interface switch is in the first state, one of the USB interface and the PCMCIA interface is selectively used. When the interface switch is in the second state, both the USB interface and the PCMCIA interface are used.

### BACKGROUND OF THE INVENTION

1. Field of the Invention

The present invention relates to electronic cards, and particularly to a Personal Computer Memory Card International Association (PCMCIA) card with multiple functions and compatibilities.

2. Description of Prior Art

Computers are necessities in everyday life because of conveniences and powerful functions that they provide. Current notebook computers include connector ports such as RS-232, PCMCIA, USB, and IEEE1394 ports for connecting to various computer peripherals namely scanners, printers, hard disks, and CD ROMs.

PCMCIA connectors are applied in most notebook computers and related computer peripherals. Card readers are installed in and connected with host machines of the notebook computer. An integrated circuit conforming to this specification is a PCMCIA card, and a slot conforming to this specification is a PCMCIA slot. PCMCIA cards have become the best connectors by eliminating troubles of having users to carry bulky peripherals. Currently on the market, types of PCMCIA cards including data cards, network interface cards, and hard disk cards are available.

Other connectors like USB connectors and IEEE1394 connectors offering advantages of high-speed and plug-and-play features are also well-known. These connectors may also be provided in certain numbers in notebook computers. Presently most notebook computers are also provided with USB slots. However, although most notebook computers have PCMCIA cards, presently most of desktop computers are seldom provided with PCMCIA slots for receiving PCMCIA cards. It is inconvenient when data is exchanged between desktop computers and notebook computers.

What is desired, therefore, is a PCMCIA card which is compatible with PCMCIA and USB slots.

### SUMMARY OF THE INVENTION

An exemplary PCMCIA card includes a USB interface, a PCMCIA interface, an interface switch, a first control circuit, a second control circuit, and a memory module. The first control circuit is connected between the PCMCIA interface and the memory module. The second control circuit is connected between the USB interface and the memory module. The interface switch is connected between the first control circuit and the second control circuit. The interface switch is changed between a first state, and a second state. When the interface switch is in the first state, one of the USB interface and the PCMCIA interface is selectively used. When the interface switch is in the second state, both the USB interface and the PCMCIA interface are used.

Other advantages and novel features will become more apparent from the following detailed description when taken in conjunction with the accompanying drawings, in which:

### BRIEF DESCRIPTION OF THE DRAWINGS

FIG. 1 is a block diagram of a PCMCIA card in accordance with a preferred embodiment of the present invention;

FIGS. 2 and 3 are isometric views of the PCMCIA card of FIG. 1, but viewed from different aspects; and

FIGS. 4 to 6 are schematic views of the PCMCIA card of FIG. 2, being used in different situations.

### DETAILED DESCRIPTION OF THE INVENTION

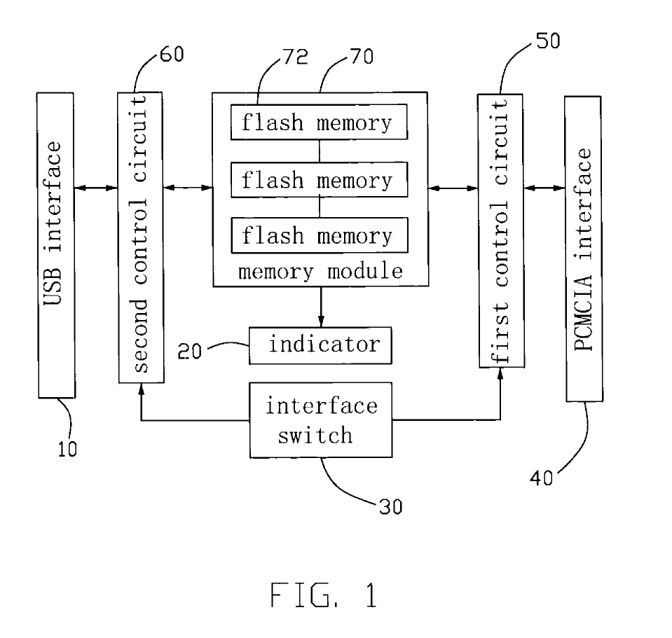

Referring to FIG. 1, a PCMCIA card 100 in accordance with a preferred embodiment of the present invention includes a Universal Serial Bus (USB) interface 10, an indicator 20, an interface switch 30, a PCMCIA interface 40, a first control circuit 50, a second control circuit 60, and a memory module 70.

The first control circuit 50 is connected between the PCMCIA interface 40 and the memory module 70, for controlling data access between the PCMCIA interface 40 and the memory module 70. The second control circuit 60 is connected between the USB interface 10 and the memory module 70, for controlling data access between the USB interface 40 and the memory module 70. The indicator 20 is connected to the memory module 70, for showing working mode of the memory module 70. The memory module 70 includes a plurality of flash memories 72 therein. The interface switch 30 is connected between the first control circuit 50 and the second control unit 60. The interface switch 30 is switchable between a first state, and a second state. When the interface switch 30 is in the first state, one of the first control circuit 50 and the second control circuit 60 turns on, while the other one of the first control circuit 50 and the second control circuit 60 turns off. Thus one of the USB interface 10 and the PCMCIA interface 40 can be selectively used. When the interface switch 30 is in the second state, the first control circuit 50 and the second control circuit 60 turn on, both the USB interface 10 and the PCMCIA interface 40 can be used.

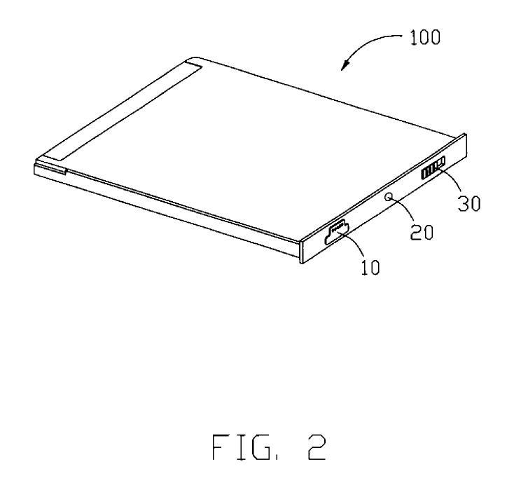

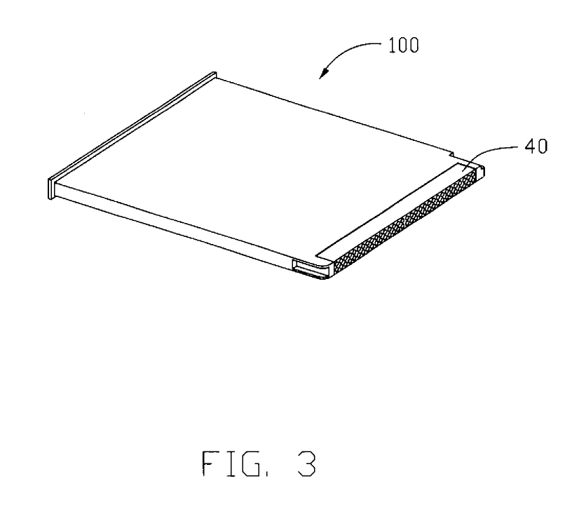

Referring to FIGS. 2 to 3, the indicator 20, the interface switch 30, and the USB interface 10 are located in a first end of the PCMCIA card 100. The PCMCIA interface 40 is located in a second end opposite to the first end of the PCMCIA card 100. In this preferred embodiment, the first end of the PCMCIA card 100 is the visible end, when the PCMCIA card 100 is received in PCMCIA slot of the computer.

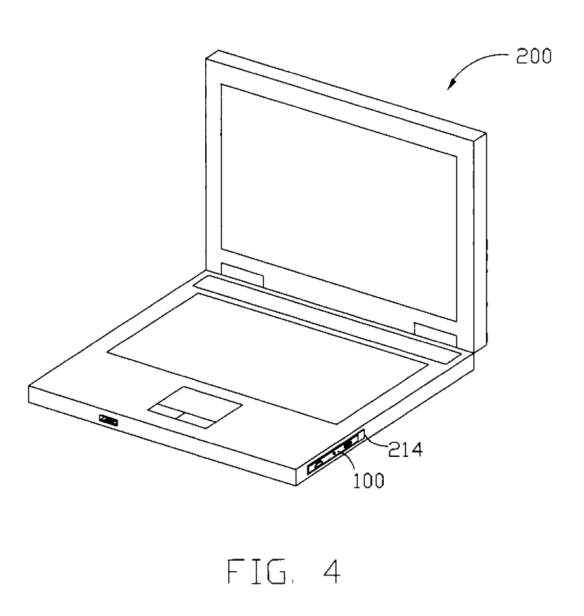

Referring to FIG. 4, in common use, the PCMCIA card 100 is inserted into a PCMCIA slot 214 of a notebook computer 200, with the interface switch 30 in the first state. The PCMCIA interface 40 is connected to a PCMCIA connector installed in the notebook computer 200.

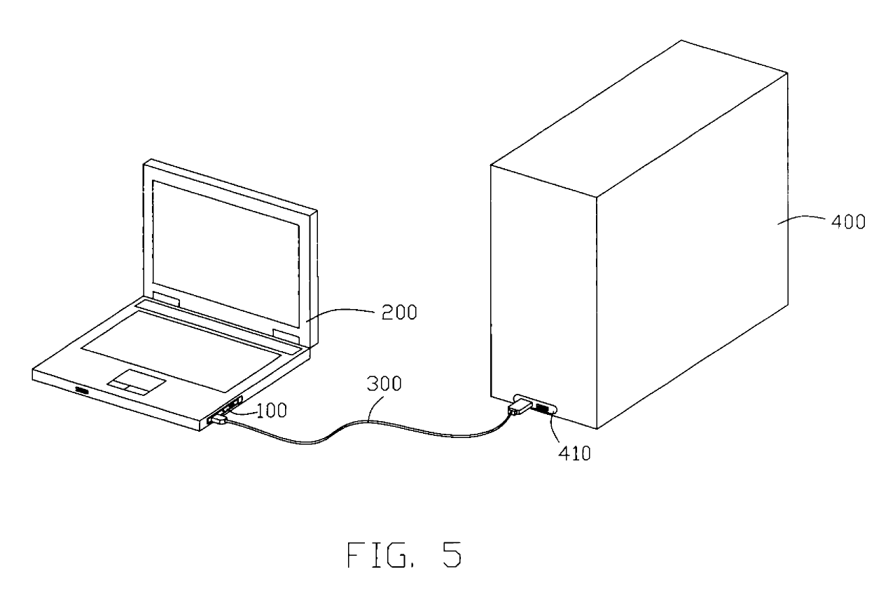

Referring to FIG. 5, to exchange data between a desktop computer 400 and the notebook computer 200, a USB cable 300 may be used. The PCMCIA card 100 is inserted into the PCMCIA slot 214 of the notebook computer 200, with the interface switch 30 in the second state. One plug of the USB cable 300 at one end is plugged into the USB interface 10 of the PCMCIA card 100 and another plug of the USB cable 300 at an opposite end is plugged into a USB slot 410 of the desktop computer 400.

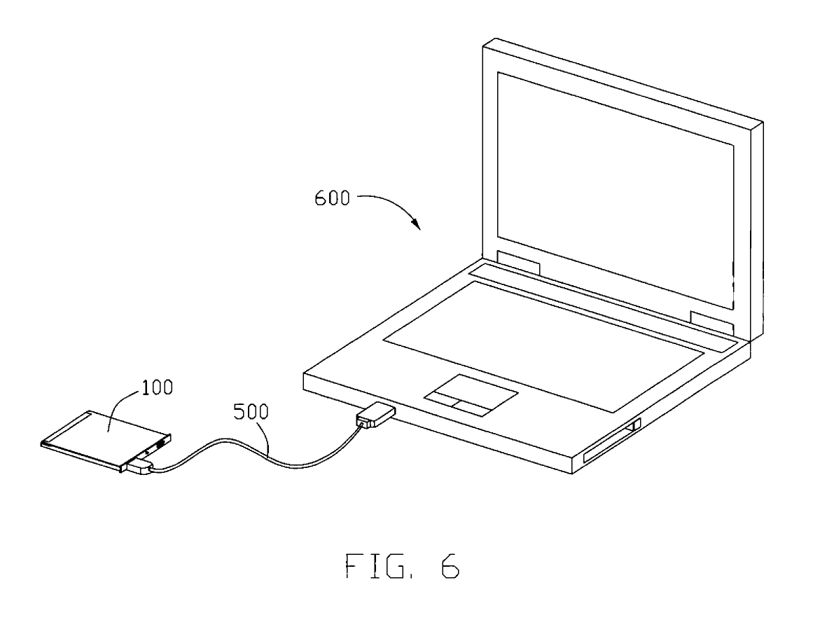

Referring to FIG. 6, when the PCMCIA card 100 is used as a portable memory, a USB cable 500 may be used. One plug of the USB cable 500 at one end is plugged into the USB interface 10 of the PCMCIA card 100 and another plug of the USB cable 500 at an opposite end is plugged into a USB slot of a notebook computer 600, with the interface switch 30 in the first state.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or exemplary embodiment of the invention.

What is claimed is:

1. A PCMCIA card comprising:
a USB interface;
a PCMCIA interface;
a memory module;
a first control circuit connected between the PCMCIA interface and the memory module;
a second control circuit connected between the USB interface and the memory module; and
an interface switch connected between the first control circuit and the second control circuit, the interface switch switchable between a first state and a second state, wherein when the interface switch is in the first state, one of the USB interface and the PCMCIA interface is capable of being selectively used; when the interface switch is in the second state, both the USB interface and the PCMCIA interface are capable of being used.

2. The PCMCIA card as claimed in claim 1, wherein the memory module comprises a plurality of flash memories installed therein.

3. The PCMCIA card as claimed in claim 1, further comprising an indicator indicating working mode of the memory module.

4. The PCMCIA card as claimed in claim 1, wherein the PCMCIA interface is connected with a PCMCIA slot of a notebook computer.

5. The PCMCIA card as claimed in claim 1, wherein the USB interface is connected to a plug of a USB cable.

6. The PCMCIA card as claimed in claim 4, wherein the USB interface is connected to a desktop computer via a USB cable which allows the notebook computer and the desktop computer to exchange data therebetween when the interface switch is in the second state.

7. The PCMCIA card as claimed in claim 1, wherein the USB interface is connected to a desktop computer via a USB cable which allows the PCMCIA card to act as a storage device for the desktop computer when the interface switch is in the first state.

8. The PCMCIA card as claimed in claim 1, wherein the USB interface is connected with a USB slot of a computer.

9. A PCMCIA card comprising:
a first interface;
a second interface;
a memory module;
a first control circuit controlling data access between the first interface and the memory module;
a second control circuit controlling data access between the second interface and the memory module; and
an interface switching controlling the PCMCIA card in a co-working mode or a selective working mode, in the co-working mode, the first interface and the second interface used at the same time, in the selective working mode, the first interface or the second interface selectively used.

10. The PCMCIA card as claimed in claim 9, wherein the first interface is a USB interface, the second interface is a PCMCIA interface.

11. The PCMCIA card as claimed in claim 10, wherein the interface switch is switchable between a first state and a second state, when the interface switch is in the first state, one of the USB interface and the PCMCIA interface is selectively used; when the interface switch is in the second state, both the USB interface and the PCMCIA interface are used at the same time.

12. The PCMCIA card as claimed in claim 9, wherein the memory module comprises a plurality of flash memories installed therein.

13. The PCMCIA card as claimed in claim 9, further comprising an indicator indicating working mode of the memory module.
